(19) United States
(12) Patent Application Publication
(10) Pub. No.: US 2025/0118537 A1
(43) Pub. Date: Apr. 10, 2025

(54) PLASMA PROCESSING APPARATUS AND HEATING APPARATUS

(71) Applicant: Hitachi High-Tech Corporation, Minato-ku, Tokyo (JP)

(72) Inventors: Hitoshi TAMURA, Tokyo (JP); Norihiko IKEDA, Tokyo (JP)

(21) Appl. No.: 18/279,755

(22) PCT Filed: Jun. 21, 2022
(86) PCT No.: PCT/JP2022/024731

§ 371 Date: Aug. 31, 2023

(51) Int. Cl. H01J 37/32

(52) U.S. Cl. CPC H01J 37/32275; H01J 37/32229; H01J 37/32293; H01J 37/32522; H01J 37/32972; H01J 2237/334

(57) ABSTRACT

In a plasma processing apparatus using a circularly polarized wave, in order to reduce an influence caused by a reflected wave and to efficiently utilize a circularly polarized wave for a plasma process, the plasma processing apparatus includes a microwave source configured to generate a microwave, a plasma processing chamber configured to process a processing target disposed therein by using plasma generated by the microwave, and a waveguide portion that includes a rectangular waveguide connected to the microwave source and a circular waveguide connected to the plasma processing chamber, and the plasma processing apparatus is further provided with, inside the circular waveguide, a reflected wave generator configured to generate a reflected wave that cancels a reflected wave propagating in the circular waveguide from a plasma processing chamber side in a state where the plasma is generated inside the plasma processing chamber by the microwave.

### TECHNICAL FIELD

The present invention relates to a plasma processing apparatus and a heating apparatus.

### BACKGROUND ART

A plasma processing apparatus is used for manufacturing a semiconductor integrated circuit element. In order to achieve performance improvement and cost reduction of the element, microfabrication of the element has been developed. In the related art, due to two-dimensional microfabrication of the element, the number of elements that can be manufactured using one processing target substrate is increased, the manufacturing cost per element is reduced, and performance improvement is also achieved due to an effect of miniaturization such as reduction in a wiring length. However, when a dimension of the semiconductor element is in the order of nanometers close to a dimension of an atom, a difficulty level of the two-dimensional microfabrication is significantly increased, and a countermeasure such as application of a new material, a three-dimensional element structure, or the like is taken. Due to these structural changes, a difficulty level of the manufacturing increases, the number of manufacturing steps increases, and an increase in the manufacturing cost is a serious problem.

Since a fatal defect occurs when a minute foreign matter or a contaminant adheres to the semiconductor integrated circuit element during the manufacturing, the semiconductor integrated circuit element is manufactured in a clean room in which the foreign matter or the contaminant is eliminated and a temperature and humidity are optimally controlled. With the microfabrication of the element, the cleanliness of the clean room required for the manufacturing increases, and the significant cost is required for construction and maintenance operations of the clean room. Therefore, efficient utilization of space in the clean room is required for the manufacturing. From this viewpoint, a semiconductor manufacturing apparatus is strictly required to be small in size and low in cost.

In addition, in-plane uniformity of the plasma process on the processing target substrate is also important. In the manufacturing of the semiconductor integrated circuit element, a disc-shaped silicon wafer having a diameter of 300 mm is often used as the processing target substrate. Although many semiconductor integrated circuit elements are usually formed on the silicon wafer, if the in-plane uniformity of the plasma process is poor, the number of non-defective products satisfying a specification that can be acquired from one silicon wafer may be reduced. Similarly, stability of the plasma process for each processing target substrate is also important. When the quality of the plasma process is not stabilized, and for example, the quality changes over time, a proportion of the non-defective product may similarly decrease.

As a plasma processing apparatus that generates plasma by an electromagnetic wave, a device using a microwave having a frequency of about several GHz, typically, 2.45 GHz as the electromagnetic wave is widely used. In particular, there is an apparatus using an electron cyclotron resonance (hereinafter, referred to as ECR) phenomenon caused by a combination of a microwave and a static magnetic field, and the apparatus has excellent characteristics, such as plasma can be generated in a relatively stable manner even under a condition in which the generation of the plasma is usually difficult, such as an extremely low pressure, or the distribution of the plasma can be controlled by the distribution of the static magnetic field.

In a plasma processing apparatus using a microwave, a magnetron is widely used as a microwave oscillator, but recently, an oscillator using a solid-state element is also used. The oscillator using a solid-state element has advantages in that an oscillation frequency and an output are more stable than those of the magnetron, various kinds of modulation are easily added, and the like. In addition, a rectangular waveguide, a circular waveguide, a coaxial line, or the like is used for the transmission of microwave power. In addition, an isolator for protecting the microwave oscillator and an automatic matching device for preventing impedance mismatching with a load are often used in combination.

As a related-art technique relating to the technical field, PTL 1 (JPH09-270386A) describes a technique of emitting a microwave toward a plasma processing chamber by a slot antenna provided below a cavity resonator so as to generate plasma with good uniformity.

In addition, PTL 2 (JP3855468B) describes a technique of improving uniformity in an azimuth angle direction by circularly-polarizing a microwave using a circularly-polarized wave generating unit so as to generate plasma.

### CITATION LIST

### Patent Literature

PTL 1: JPH09-270386A
PTL 2: JP3855468B

### SUMMARY OF INVENTION

### Technical Problem

PTL 1 relates to a technique of emitting a microwave toward a plasma processing chamber by a slot antenna provided below a cavity resonator so as to generate plasma with good uniformity, and describes a case in which the microwave is supplied to the cavity resonator in a TEM mode which is a lowest-order mode of a coaxial line, but in order to reduce reflection at a connection portion with the cavity resonator, connection via the coaxial line having a line length of ¼ wavelength and having a different internal conductor diameter or external conductor diameter is performed.

In the configuration disclosed in PTL 1, the TEM mode of the coaxial line in which an electromagnetic field does not change in the azimuth angle direction is used. Therefore, it is not necessary to achieve the temporal uniformity in the azimuth angle direction by using a circularly polarized wave, and this concept is not included.

In addition, the line length of the line for reflected wave reduction is limited to the ¼ wavelength, and the reflected wave reduction using reflected waves at an upper end and a lower end of the line is disclosed. Further, it is described that a matching chamber is interposed in the connection portion at which the reflection occurs, and it is described that a height and a diameter of the matching chamber are optimized to cancel the reflected wave. However, regarding a method of adjusting the height and the diameter, only optimization is described, and a method for the optimization is not disclosed.

Although PTL 1 discloses the method of using the line having the length of ¼ wavelength, a method of obtaining an optimum dimension for the reflected wave reduction is not disclosed, it is necessary to repeatedly perform an experiment by trial and error to obtain the optimum dimension, and there is a problem that a significant amount of labor, time, funds, and the like are required.

Further, in a case of a plasma processing apparatus using a circularly polarized wave, a structure for the reflected wave reduction described above is required to be a structure that does not inhibit the circularly polarized wave. That is, when the circularly polarized wave is incident on the structure for the reflected wave reduction, it is necessary that an axial ratio of a passing through electromagnetic wave is not deteriorated.

Further, in a case of using a monitor device for optically observing the processing target substrate via a waveguide path for supplying the microwave, blocking the path for optical observation by the structure for the reflected wave reduction is required to be avoided.

In addition, although PTL 2 discloses that the uniformity in the azimuth angle direction is improved by circularly-polarizing the microwave using the circularly-polarized wave generating unit so as to generate plasma, the plasma processing apparatus often has an axisymmetric configuration corresponding to the processing of the disc-shaped processing target substrate.

In the configuration disclosed in PTL 2, a circular waveguide is also disposed coaxially with the apparatus so as to transmit the microwave power in a TE₁₁ mode which is a lowest-order mode of the circular waveguide. It is intended to generate plasma uniform in the azimuth angle direction by setting the configuration of the apparatus to be coaxially axisymmetric with the processing target substrate. However, the TE₁₁ mode which is the lowest-order mode of the circular waveguide is a mode that changes in the azimuth angle direction, so that due to the circularly-polarizing, the plasma having an excellent axial symmetry property is generated by setting an axisymmetric power distribution as an average of the microwave for one period.

As disclosed in PTL 2, in a case where the microwave circularly-polarized by the circularly-polarized wave generating unit is transmitted through the circular waveguide, and the plasma uniform in the azimuth angle direction is generated by the microwave, when a reflection coefficient as viewed on a load side from the circular waveguide is large, various failures, for example, an operation failure relating to the circularly-polarizing performed by the circularly-polarized wave generating unit, an ignition failure of the plasma, an abnormal discharge resulting from a large standing wave caused by a large reflected wave, and the like may be problems.

Further, the circularly-polarized wave generating unit is often designed based on a case where the reflection coefficient on the load side is zero, and thus when the reflection coefficient of a load is large, the circularly polarized wave cannot be generated well, and an electromagnetic field uniform in the azimuth angle direction may not be achieved.

The invention solves the problems in the related art described above, and provides a plasma processing apparatus that uses a circularly polarized wave and enables to reduce an influence caused by a reflected wave and to efficiently utilize a circularly polarized wave for plasma process, and a heating apparatus.

### Solution to Problem

In order to solve the problems described above, the invention provides a plasma processing apparatus including: a processing chamber configured to plasma-process a sample; a radio frequency power supply configured to supply, via a circular waveguide, radio frequency power of a microwave; a monitor device configured to optically monitor a plasma state via the circular waveguide; a circularly polarized wave generator disposed inside the circular waveguide and configured to generate a circularly polarized wave; and a sample stage allowing the sample to be placed thereon, in which the plasma processing apparatus further includes a reflected wave generator disposed between the circularly polarized wave generator and the processing chamber and inside the circular waveguide, the reflected wave generator generates a reflected wave that cancels, without inhibiting the circularly polarized wave, a reflected wave propagating from the processing chamber, and an optical path for optically monitoring the plasma state is formed in the reflected wave generator.

Further, in order to solve the problems described above, the invention provides a heating apparatus including: a heating chamber configured to heat a sample; a radio frequency power supply configured to supply, via a circular waveguide, radio frequency power of a microwave; and a circularly polarized wave generator disposed inside the circular waveguide and configured to generate a circularly polarized wave, in which the heating apparatus further includes a reflected wave generator disposed between the circularly polarized wave generator and the heating chamber and inside the circular waveguide, and the reflected wave generator generates a reflected wave that cancels, without inhibiting the circularly polarized wave, a reflected wave propagating from the heating chamber.

### Advantageous Effects of Invention

According to the invention, since the microwave power is efficiently supplied to the processing chamber by using a configuration in which the reflected wave is suppressed, a condition range in which the plasma can be generated is expanded, and the microwave power can be more effectively utilized.

In addition, in the plasma processing apparatus using the monitor device for observing the circularly polarized wave or optically observing the processing target substrate, it is possible to secure an optical path without inhibiting the circularly polarized wave.

### BRIEF DESCRIPTION OF DRAWINGS

FIG. 1 is a cross-sectional side view of a microwave plasma etching apparatus in the related art.

FIG. 2 is a cross-sectional side view of a microwave plasma etching apparatus according to a first embodiment of the invention.

FIG. 3A-1 is a plan view illustrating a reflected wave generator according to the first embodiment of the invention, and FIG. 3A-2 is a cross-sectional side view.

FIG. 3B-1 is a plan view illustrating the reflected wave generator in which notched portions are formed at four positions according to the first embodiment of the invention, and FIG. 3B-2 is a cross-sectional side view.

FIG. 3C-1 is a plan view illustrating the reflected wave generator in which notched portions are formed at two positions according to the first embodiment of the invention, and FIG. 3C-2 is a cross-sectional side view.

FIG. 4 is a cross-sectional side view of a heating apparatus using a microwave according to a second embodiment of the invention.

FIG. 5 is a cross-sectional side view illustrating the reflected wave generator according to the first and second embodiments of the invention.

### DESCRIPTION OF EMBODIMENTS

The invention relates to a plasma processing apparatus for generating plasma by a microwave in which the plasma having high spatial uniformity can be stably generated and maintained by efficiently supplying power of the microwave to a processing chamber spatially uniformly, and relates to a heating apparatus using a microwave in which microwave power can be efficiently supplied to a processing target spatially uniformly.

As a known method for handling a microwave circuit that transmits an electromagnetic wave such as a microwave, there is a scattering matrix. A microwave circuit including a plurality of (n) ports for inputting and outputting a microwave is considered, and an incident wave and a reflected wave at each port are defined. As the ports, in addition to physical entrances/exits for the microwave, a case of considering a plurality of modes for one entrance/exit is also included. For example, in a circular waveguide, a plurality of modes having different polarization planes can also be set as ports on a certain surface of the circular waveguide.

Regarding an incident wave vector with an incident wave iⱼ (j=1 to n) at each port as an element and a reflected wave vector with a reflected wave rⱼ (j=1 to n) as an element, a matrix indicating a relation between the incident wave vector and the reflected wave vector, which is indicated by (Formula 1), is referred to as the scattering matrix. When the number of input and output ports is one, the scattering matrix is a scalar and corresponds to a reflection coefficient. Each element of the scattering matrix is a complex number, and has a magnitude and a phase, or a real part and an imaginary part.

Although the scattering matrix may be theoretically obtained when the microwave circuit as a target is simple, even when a shape is complicated, the scattering matrix can be obtained by performing electromagnetic field analysis according to a numerical method such as a finite element method. Further, the scattering matrix can also be measured by using a measuring instrument such as a network analyzer.

$$\begin{matrix}[ MATH . 1 ] & \\ [ \begin{matrix}{r}_{1} \\ ⋮ \\ {r}_{n}\end{matrix} ] = [ \begin{matrix}{s}_{11} & ⋯ & {s}_{n 1} \\ ⋮ & ⋱ & ⋮ \\ {s}_{1 n} & ⋯ & {s}_{nn}\end{matrix} ] [ \begin{matrix}{i}_{1} \\ ⋮ \\ {i}_{n}\end{matrix} ] & ( Formula 1 )\end{matrix}$$

$$[ \begin{matrix}{r}_{1} \\ ⋮ \\ {r}_{n}\end{matrix} ] : reflected wave vector$$

$$[ \begin{matrix}{i}_{1} \\ ⋮ \\ {i}_{n}\end{matrix} ] : incident wave vector$$

$$[ \begin{matrix}{s}_{11} & ⋯ & {s}_{n 1} \\ ⋮ & ⋱ & ⋮ \\ {s}_{1 n} & ⋯ & {s}_{nn}\end{matrix} ] : scattering matrix$$

n: the number of the input and output ports for the microwave

For example, when it is assumed that a loss is small to such an extent that can be ignored, a scattering matrix of a waveguide having an in-waveguide wavelength λ and a length L is known that it is represented as follows.

$$\begin{matrix}[ MATH . 2 ] & \\ [ \begin{matrix}0 & exp ( - j \frac{2 π}{λ} L ) \\ exp ( - j \frac{2 π}{λ} L ) & 0\end{matrix} ] & ( Formula 2 )\end{matrix}$$

Here, j is an imaginary unit.

When the microwave circuit is reversible, it is known that the following formula is established, and the scattering matrix is a target matrix.

$$\begin{matrix}[ MATH . 3 ] & \\ {s}_{ij} = {s}_{j i} & ( Formula 3 )\end{matrix}$$

Further, when the microwave circuit is a passive circuit and has no loss, it is known that the scattering matrix is a unitary matrix.

In general, a matching device is used to efficiently supply the power of the microwave to a load. The matching device is loaded in a transmission path between a microwave source and the load, and operates to ideally eliminate a reflected wave generated by the load. That is, the reflected wave generated by the load is canceled by using the matching device, and the power of the incident microwave is efficiently consumed by the load. The matching device includes two ports on a microwave source side and a load side, and can be modeled by using a 2×2 scattering matrix. An internal parameter of the matching device is optimally controlled according to a reflection coefficient of the load so as to eliminate the reflected wave. As the matching device, a three-stub tuner in which three stubs each having a variable insertion length are loaded in a rectangular waveguide, an EH tuner in which a branch having a variable length is provided on each of an E surface and an H surface of a rectangular waveguide, or the like is used. Further, an automatic matching device is also used that combines a mechanism for monitoring the reflected wave and the reflection coefficient of the load, a driving mechanism and a control mechanism for a matching element in the matching device, and the like to automatically perform a matching operation.

In addition, the quality of a plasma process may be improved by applying RF bias power to a processing target substrate. For example, in a case of a plasma etching process, a direct current bias voltage caused by a mass difference between ions and electrons is generated on the processing target substrate due to an RF bias of a frequency of about 400 kHz to 13.56 MHz, and ions in the plasma are drawn by the direct current bias voltage so as to improve perpendicularity of a machining shape, increase a machining speed, and the like, and whereby the quality of the plasma process can be improved.

Many structures are proposed as a method of supplying a microwave into a plasma processing chamber. An electromagnetic field distribution of the microwave in the plasma processing chamber and a plasma distribution resulting therefrom are affected by the method of supplying the microwave, and the uniformity of the plasma process to be applied to the processing target substrate is affected, which is one of factors.

A silicon wafer having a diameter of 300 mm is often used as the processing target substrate used in the manufacturing of a semiconductor integrated circuit. Since it is necessary to perform the uniform plasma processing on the disc-shaped processing target substrate, the plasma processing apparatus often has a structure that is axisymmetric with respect to a center of the processing target substrate. Further, the microwave may also be supplied in consideration of an axial symmetry property of the plasma processing, for example, a coaxial line may be disposed coaxially with a central axis so as to transmit the microwave in a TEM mode in which an electromagnetic field that does not change in an azimuth angle direction, or the circular waveguide may be disposed coaxially with the central axis so as to circularly-polarize and transmit the microwave in a lowest-order TE₁₁ mode.

A ratio of a maximum value of a magnitude of a microwave electric field vector in one period of the microwave to a minimum value may be referred to as an axial ratio, and may be used as an index for evaluating a degree of a circularly polarized wave. A case where the electric field vector rotates clockwise with respect to a propagating direction of the electromagnetic wave is referred to as negative, and a case where the electric field vector rotates counterclockwise is referred to as positive. When the magnitude of the axial ratio is 1, the magnitude of the electric field vector does not change, and a perfect circularly polarized wave whose direction rotates is obtained. In addition, when the magnitude of the axial ratio is infinite, a linearly polarized wave whose polarization plane does not rotate is obtained. When the magnitude of the axial ratio takes other values, the microwave is referred to as an elliptically polarized wave. In the TE₁₁ mode which is the lowest-order mode of the circular waveguide, the axial ratio is evaluated by an electric field vector on a central axis of the circular waveguide.

Generally, the circularly polarized wave can be obtained by superimposing linearly polarized waves having different polarization planes and a phase difference. Here, the polarization plane refers to a plane including a propagating direction and an electric field vector of a wave. For example, by superimposing two waves having the same amplitude, whose polarization planes orthogonal to each other and which have a phase difference of 90 degrees, a perfect circularly polarized wave in which the magnitude of the axial ratio is 1 can be obtained. When the amplitude, the phase difference, and an angle of the polarization planes of the two waves deviate from these values, an elliptically polarized wave is obtained. Generally, when n linearly polarized waves having the same amplitude are superimposed, the perfect circularly polarized wave can be obtained by setting the polarization planes to form an angle of 180 degrees/n with each other, and setting the phase difference to 180 degrees/n.

Generally, when there is a discontinuous portion in a transmission path of the microwave, a reflected wave is generated. In a structure in which the microwave is supplied into the plasma processing chamber, for example, when the circular waveguide is enlarged in a stepwise manner, the reflected wave is also generated due to the enlargement.

When a structure for achieving the optimal electromagnetic field distribution in the plasma processing chamber from the viewpoint of plasma uniformity is complicated, the microwave power may not be efficiently transmitted into the processing chamber due to an influence caused by the reflected waves generated in the parts. Therefore, it is desirable to simplify the structure as much as possible, but it is often difficult to achieve both of the simplification and the desirable electromagnetic field. Although the matching device described above is used as a countermeasure, when a degree of mismatching with the load is too large, it may become difficult to secure a wide matching range corresponding to the degree, and a large standing wave may be generated between the matching device and the load, which may cause problems such as abnormal discharge and power loss.

An in-situ observation during the plasma process is effective in improving the quality of the plasma process, shortening a processing time, and the like. Regarding the in-situ observation, there are various methods depending on the plasma process, for example, in a case of the plasma etching process, control such as directly observing the processing target substrate during the process, measuring a film thickness of an etching target film in real time, and stopping the process when the film thickness reaches a desired film thickness may be performed. As compared with a case without performing the in-situ observation, there are advantages such as a processing film thickness can be stabilized and the processing time can be shortened. In addition, there is an advantage that in a case where an abnormality of the apparatus is found by the in-situ observation, it is also possible to immediately take a countermeasure such as stopping the process.

An optical interference of the processing target substrate can be used in film thickness measurement of the etching target film. There are a method of irradiating the processing target substrate with reference light from the outside, a method of using a specific wavelength of plasma emission light, and the like. In this case, it is necessary to prepare a window for observation as a structure allowing optical observation of the processing target substrate during the plasma etching process.

A heating apparatus that irradiates a processing target with a microwave to heat the processing target is used. As the processing target, there are food, wood and substances corresponding to various materials such as ceramics. As compared with a heating apparatus of another form, for example, a heating apparatus that applies heat of a high-temperature heat source to the processing target by heat transfer, since the processing target can be directly heated in the apparatus using a microwave, there are advantages that the heating can be performed efficiently with less power loss, and further, the temperature can be increased quickly. Further, since a wavelength of the microwave is short, it is also possible to converge the microwave into a beam shape, and it is also possible to spatially heat only a desired portion by irradiating only the processing target with the microwave in a concentrated manner. Further, there is also an advantage that only a specific processing target can be selectively heated by using a property that the loss of the microwave differs depending on a physical property value of the processing target.

On the other hand, in the heating apparatus using a microwave, if the control on the electromagnetic field distribution of the microwave is not appropriate, heating may be unevenness such as a part of the processing target is not heated spatially due to the short wavelength. For example, when a microwave having a frequency of 2.45 GHz is used, a standing wave tends to be generated at intervals of about 61 mm, which is a half of a wavelength of 122 mm in a free space, in a closed space, and the heating unevenness may occur at such an interval. As a countermeasure, the processing target may be moved and rotated, a member reflecting the microwave may be moved and rotated, or the like.

In the plasma processing apparatus using the microwave, the plasma is generated by supplying a strong electromagnetic field of the microwave inside the processing chamber, so that it is clear that ignitability of the plasma is deteriorated when the reflection coefficient of the load is large and the electromagnetic field in the processing chamber is relatively weak. In addition, it is clear that when the reflection coefficient of the load is large, the standing wave generated by the superimposition of the reflected wave and the incident wave also increases, and the risk of the abnormal discharge caused by the standing wave also increases. In particular, in a case of using the matching device, it is clear that a matching failure occurs when the reflection coefficient exceeds the matching range of the matching device.

Further, even in a case where the reflection coefficient of the load is within the matching range of the matching device, when the reflection coefficient of the load is large, power durability of the matching device decreases, and a risk of causing failures such as the abnormal discharge increases. For example, in a case of a matching device using a stub, when the reflection coefficient of the load is high, an operation needs to be performed in a region where an insertion length of the stub into the waveguide is large, and thus an electric field generated between a tip end of the stub and a waveguide wall increases, and the risk of the abnormal discharge increases.

Therefore, in order to achieving a reflected wave reducing structure capable of securing an optical path without inhibiting the circularly polarized wave in the plasma processing apparatus that includes a monitor device for observing the circularly polarized wave and optically observing the processing target substrate, according to the invention, the plasma processing apparatus having the substantially axisymmetric structure and generating the plasma by using the microwave includes a circularly polarized wave generator for transmitting the microwave power for plasma generation through the circular waveguide, that is disposed on the central axis and operates in a single mode, and generating the circularly polarized wave inside the circular waveguide, and includes a discontinuous portion that does not inhibit the circularly polarized wave on a processing chamber side of the circularly polarized wave generator, a reflected wave having a desired phase and amplitude is generated at the discontinuous portion, and a reflected wave generated by a plasma source structure on the processing chamber side is cancelled by the generated reflected wave.

Accordingly, it is possible to implement a structure that does not inhibit the circularly polarized wave propagating in the circular waveguide and has substantially any reflection coefficient, and to adjust the magnitude and the phase of the reflection coefficient to cancel the reflected wave from the plasma processing chamber side.

In addition, in the case of the heating apparatus using a microwave, there are also the same problems as those of the plasma processing apparatus described above. That is, it is necessary to efficiently and uniformly supply the microwave power to a member as a heating target, when the reflected wave in the transmission path of the microwave power is large, the power loss and the abnormal discharge may occur. However, in the invention, the discontinuous portion that transmits the microwave power via the waveguide and generates a desired reflected wave at a predetermined position in the waveguide is provided, a reflected wave generated on a load side of the waveguide is canceled by the reflected wave generated by the discontinuous portion, and thus the problems are solved.

In a case where the invention is applied in a plasma processing apparatus, by connecting a discontinuous portion having a configuration as to be described below to the load, the structure that does not inhibit the circularly polarized wave propagating in the circular waveguide and has substantially any reflection coefficient can be implemented, and the reflected wave from the plasma processing chamber side can be canceled by adjusting the magnitude and the phase of the reflection coefficient.

For example, the discontinuous portion is implemented by a short circular waveguide that has a small inner diameter. For example, in a case of a circular waveguide that transmits a microwave of a frequency of 2.45 GHz and has an inner diameter of 90 mm, for example, a circular waveguide portion having an inner diameter of less than 90 mm and a length of 25 mm is provided as the discontinuous portion. Qualitatively, when the inner diameter of the discontinuous portion is further reduced, the reflection coefficient can increase, and when a position of the discontinuous portion is changed, the phase of the reflection coefficient can be adjusted. An in-waveguide wavelength of the circular waveguide having the inner diameter of 90 mm is 202.5 mm when the frequency is 2.45 GHz. That is, the phase can be adjusted to any value of 0 radian to 2π radians by moving the position within a range of one wavelength in the circular waveguide. Further, since the discontinuous portion is implemented by the circular waveguide, the circularly polarized wave is not inhibited. As described above, the circularly polarized wave can be described to be obtained by superimposing two linearly polarized waves having orthogonal polarization planes, but since the discontinuous portion is implemented by the circular waveguide, a scattering matrix of the discontinuous portion does not depend on a polarization plane of an incident wave, and the scattering matrix does not change even when the incident wave is incident on the polarization plane at any angle.

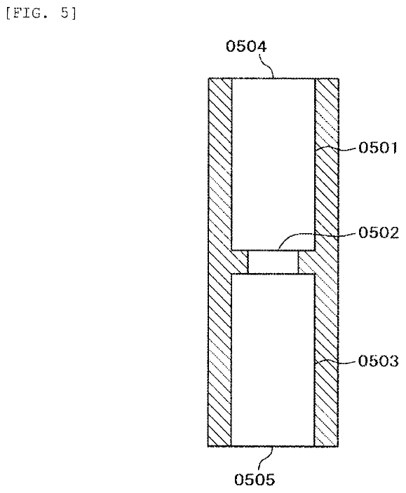

FIG. 5 illustrates a model for numerically obtaining the scattering matrix for the discontinuous portion implemented by a short circular waveguide that has a small inner diameter. The circular waveguide 0502 constituting the discontinuous portion is the circular waveguide 0502 that has the inner diameter of less than 90 mm and the length of 25 mm as described above, and circular waveguides 0501 and 0503 each having an inner diameter of 90 mm and a length of 100 mm are connected to front and rear portions of the circular waveguide 0502. The circular waveguide 0502 constituting the discontinuous portion having a reduced diameter and the circular waveguide 0501 and the circular waveguide 0503 share the central axis. In addition, a port 1(504) and a port 2(505) are set in the circular waveguides 0501 and 0503, respectively.

It is assumed that the circular waveguides 0501 and 0503 each having the inner diameter of 90 mm, which operate at a frequency of 2.45 GHz, only allows the propagation of the TE₁₁ mode that is the lowest mode, and a linearly polarized wave in the TE₁₁ mode is input to or output from the two ports 0504 and 0505. The scattering matrix in the model is a 2×2 matrix.

In a case of using the model shown in FIG. 5 at a frequency of 2.45 GHz, the scattering matrix is numerically obtained by variously changing the inner diameter of the circular waveguide 0502 constituting the discontinuous portion to solve a Helmholtz formula, which is a basic formula of the electromagnetic field, by the finite element method. Results thereof are shown in Table 1.

In Table 1, magnitudes (described in an amp column in the table) and phases (described in an arg column in the table) of elements (s₁₁, s₁₂, s₂₁, s₂₂) of the scattering matrix are shown. It is shown that as the diameter of the circular waveguide 0502 constituting the discontinuous portion is close to 90 mm, the magnitudes of s₁₁ and s₂₂ tend to decrease, the magnitudes of s₁₂ and s₂₁ tend to increase, and reflection by the circular waveguide 0502 constituting the discontinuous portion decreases.

It is known that, by selecting the diameter of the circular waveguide portion in the range shown in Table 1, the magnitude or the amplitude of the reflected wave generated by the circular waveguide 0502 constituting the discontinuous portion can be adjusted to about 0.9. Further, the phase of the reflected wave can be adjusted by a distance between the circular waveguide 0502 constituting the discontinuous portion and the load. That is, since the amplitude and the phase of the reflected wave generated by the circular waveguide 0502 constituting the discontinuous portion can be set substantially freely, the reflected wave generated by the load can be canceled without inhibiting the circularly polarized wave.

In addition, since the microwave circuit has the reversibility and is a passive circuit that has no loss as described above, s₁₂ and s₂₁ are equal to each other, and a sum of squares of the magnitude of su and the magnitude of s₁₂ is 1. Further, since the port 1 and the port 2 are set to have a symmetrical structure, s₁₁ and s₂₂ are equal to each other.

TABLE 1

| | s₁₁ | | s₁₂ | | s₂₁ | | s₂₂ | | s₁₁/(s₁₁²-s₁₂²) | |
|---|---|---|---|---|---|---|---|---|---|---|
| Diameter | | arg | | arg | | arg | | arg | | arg |
| (mm) | amp | (rad) | amp | (rad) | amp | (rad) | amp | (rad) | amp | (rad) |
| 60 | 0.9021 | 2.5186 | 0.4315 | −2.194 | 0.4315 | −2.194 | 0.9021 | 2.518 | 0.9021 | −2.519 |
| 62 | 0.8563 | 2.3948 | 0.5166 | 0.8226 | 0.5166 | 0.8226 | 0.8563 | 2.392 | 0.8563 | −2.394 |
| 64 | 0.7955 | 2.2542 | 0.606 | −2.456 | 0.606 | −2.456 | 0.7955 | 2.2578 | 0.7955 | −2.256 |
| 66 | 0.7244 | 2.1235 | 0.6894 | 0.5494 | 0.6894 | 0.5494 | 0.7244 | 2.117 | 0.7244 | −2.12 |
| 68 | 0.6341 | 1.9671 | 0.7732 | −2.746 | 0.7732 | −2.746 | 0.6341 | 1.9654 | 0.6341 | −1.966 |
| 70 | 0.5461 | 1.8213 | 0.8377 | 0.26 | 0.8377 | 0.26 | 0.5461 | 1.8403 | 0.5461 | −1.835 |
| 72 | 0.4553 | 1.7015 | 0.8904 | 0.127 | 0.8904 | 0.127 | 0.4553 | 1.6941 | 0.4553 | −1.696 |
| 74 | 0.3739 | 1.582 | 0.9275 | −3.127 | 0.9275 | −3.127 | 0.3739 | 1.5881 | 0.3739 | −1.587 |
| 76 | 0.289 | 1.4686 | 0.9573 | 3.0383 | 0.9573 | 3.0383 | 0.289 | 1.4664 | 0.289 | −1.467 |
| 78 | 0.2294 | 1.3897 | 0.9733 | 2.9527 | 0.9733 | 2.9527 | 0.2294 | 1.3741 | 0.2294 | −1.375 |
| 80 | 0.1669 | 1.3015 | 0.986 | −0.275 | 0.986 | −0.275 | 0.1669 | 1.2894 | 0.1669 | −1.29 |
| 82 | 0.1192 | 1.2305 | 0.9929 | 2.7958 | 0.9929 | 2.7958 | 0.1192 | 1.2196 | 0.1192 | −1.22 |
| 84 | 0.0783 | 1.1724 | 0.9969 | 2.7327 | 0.9969 | 2.7327 | 0.0783 | 1.1514 | 0.0783 | −1.151 |
| 86 | 0.0459 | 1.1131 | 0.9989 | −0.46 | 0.9989 | −0.46 | 0.0459 | 1.1086 | 0.0459 | −1.109 |
| 88 | 0.021 | 1.0485 | 0.9998 | −0.504 | 0.9998 | −0.504 | 0.021 | 1.085 | 0.021 | −1.085 |

When the reflection coefficient of the load is known by a method such as measurement or calculation as described above, the reflected wave can be reduced by using the circular waveguide 0502 constituting the discontinuous portion. The optimal discontinuous portion can be obtained by using the scattering matrix.

When the circular waveguide 0502 having the length L and constituting the discontinuous portion is connected to the load having a reflection coefficient Rₚ, a reflection coefficient Rₚ′ on a waveguide end surface of the circular waveguide 0502 constituting the discontinuous portion is obtained as Formula 4 by using (Formula 2).

$$\begin{matrix}[ MATH . 4 ] & \\ {R}_{p}^{′} = {R}_{p} exp ( - j \frac{4 π}{λ} L ) & ( Formula 4 )\end{matrix}$$

That is, by connecting the circular waveguide 0502 having the length L and constituting the discontinuous portion, the phase of the reflection coefficient of the load can be controlled by the length L.

Further, in a case where the circular waveguide 0502 constituting the discontinuous portion shown in FIG. 5 and Table 1 is connected,

$$\begin{matrix}[ MATH . 5 ] & \\ {R}_{p}^{′′} = {s}_{11} + \frac{{s}_{21} {s}_{12} {R}_{p}^{′}}{1 - {s}_{22} {R}_{p}^{′}} & ( Formula 5 )\end{matrix}$$

a reflection coefficient Rₚ″ can be written as above.

Further, since s₁₁=s₂₂ and s₂₁=s₁₂ due to conditions that includes the reversibility, the passive circuit, the lossless and the symmetry structure, the reflection coefficient Rₚ″ is as follows.

$$\begin{matrix}[ MATH . 6 ] & \\ {R}_{p}^{′′} = {s}_{11} + \frac{{s}_{12}^{2} {R}_{p}^{′}}{1 - {s}_{11} {R}_{p}^{′}} & ( Formula 6 )\end{matrix}$$

In order to set the Rₚ″ to zero,

$$\begin{matrix}[ MATH . 7 ] & \\ {R}_{p}^{′} = \frac{{s}_{11}}{{s}_{11}^{2} - {s}_{12}^{2}} & ( Formula 7 )\end{matrix}$$

The above formula should be held.

Since a phase of the Rₚ′ can be freely controlled by using the length L of the circular waveguide 0502 constituting the discontinuous portion based on (Formula 4), it is sufficient to adjust a magnitude of a right side of (Formula 7) according to a magnitude of the Rₚ′ or the Rₚ. That is, since the magnitude of the Rₚ′ or the Rₚ is a value of 0 or more and 1 or less, it is sufficient to adjust the magnitude of the right side of (Formula 7) within a range of 0 to 1.

Values of the right side of (Formula 7) are shown in Table 1. It can be seen that the magnitude of Rₚ′ can be adjusted within a range that is approximately close to 0.9. That is, by selecting the optimum length L of the circular waveguide 0502 constituting the discontinuous portion, the overall reflected wave Rₚ″ can be ideally adjusted to zero with the reflection coefficient Rₚ of the load in a range of small than about 0.9.

Embodiments of the invention based on the above consideration will be described in detail with reference to the drawings. In all the drawings illustrating the present embodiment, components having the same function are denoted by the same reference numerals, and a repeated description thereof is omitted in principle.

However, the invention should not be construed as being limited to the description of the embodiments to be described below. A person skilled in the art could have easily understood that a specific configuration can be changed without departing from the spirit or gist of the invention.

### Embodiment 1

As an example of applying the invention to a plasma processing apparatus that uses plasma generated by radio frequency power of a microwave, and includes a monitor device for optically monitoring a state of a plasma process, and a circularly polarized wave generator, a plasma processing apparatus is described in which a discontinuous portion that secures an optical path of the monitor device and cancels a reflected wave without inhibiting a circularly polarized wave is disposed inside a circular waveguide and below the circularly polarized wave generator.

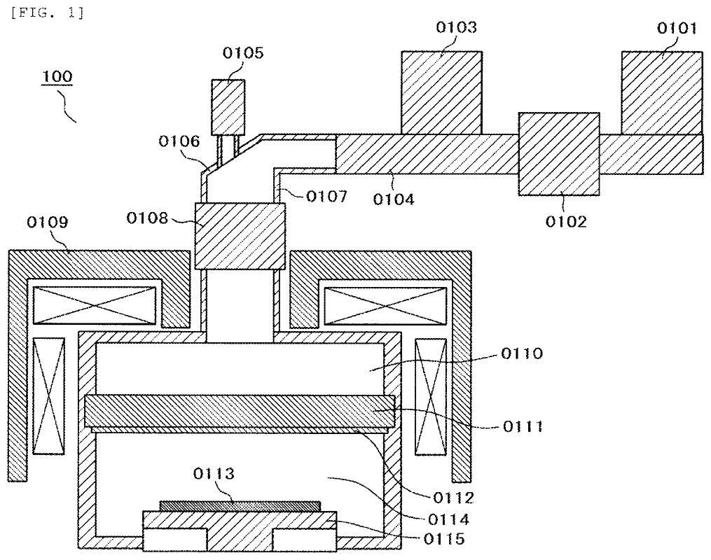

As an example of the plasma processing apparatus in the related art that is the precondition of the embodiment, a plasma processing apparatus 100 that performs a microwave plasma etching process in the related art is described with reference to FIG. 1. FIG. 1 illustrates a vertical cross-sectional view of the entire plasma processing apparatus 100 in the related art. The plasma processing apparatus 100 includes a microwave oscillator 0101, an isolator 0102, an automatic matching device 0103, a rectangular waveguide 0104, a measuring instrument 0105, a circle-rectangle converter 0106, a circular waveguide 0107, a circularly polarized wave generator 0108, a static magnetic field generator 0109, a cavity portion 0110, a dielectric window 0111, a shower plate 0112, a plasma processing chamber 0114, and a placing table 0115 on which a processing target substrate 0113 is placed.

In such a configuration, the microwave having a frequency of 2.45 GHz output by the microwave oscillator 0101 is transmitted to the circle-rectangle converter 0106 by the rectangular waveguide 0104 via the isolator 0102 and the automatic matching device 0103. A rectangular waveguide that operates in a TE₁₀ mode which is a lowest-order mode is used as the rectangular waveguide 0104. The isolator 0102 has a function of preventing the reflected wave generated on the load side from being incident on and damaging the microwave oscillator 0101. The automatic matching device 0103 operates to monitor the reflected wave on the load side or an impedance and automatically reduce the reflected wave by adjusting an internal parameter. The automatic matching device 0103 may be a manual matching device in order to reduce apparatus cost and simplify the apparatus.

A magnetron is used as the microwave oscillator 0101. The circle-rectangle converter 0106 also serves as a corner for bending a propagating direction of the microwave by 90 degrees so as to reduce a size of the entire apparatus. The circular waveguide 0107 and the circularly polarized wave generator 0108 loaded in the circular waveguide are loaded below the circle-rectangle converter 0106, so as to convert the microwave incident as a linearly polarized wave into a circularly polarized wave. The circular waveguide 0107 is provided on a substantially central axis of the plasma processing chamber 0114, and the circularly-polarized microwave generated by the circularly polarized wave generator 0108 is transmitted. On a load side of the circular waveguide 0107, the plasma processing chamber 0114 that includes the placing table 0115 for placing the processing target substrate 0113 with the cavity portion 0110, the dielectric window 0111, and the shower plate 0112 interposed is provided. A central axis of the placing table 0115 is set to be coincide with the central axis of the plasma processing chamber 0114 and a central axis of the circular waveguide 0107.

The cavity portion 0110 has a function of alleviating central concentration of the electromagnetic field of the supplied microwave. As the dielectric window 0111 and the shower plate 0112, a material having a small loss with respect to the microwave and being unlikely to adversely affect the plasma process is desirable, and quartz is used. To the plasma processing chamber 0114, a gas supply system (not shown) is connected and a gas used for the etching process is supplied in a shower form through a minute gap (not shown) between the dielectric window 0111 and the shower plate 0112 and a plurality of minute supply holes provided in the shower plate 0112. Further, a vacuum exhaust system (not shown) is connected to the plasma processing chamber 0114 via a pressure gauge (not shown) and a conductance variable valve (not shown) for adjusting an exhaust speed.

The plasma processing chamber 0114 can be held in a desired pressure and a gas atmosphere suitable for the plasma etching process by these instruments. The processing target substrate 0113 is provided in the plasma processing chamber 0114, and the plasma etching process is performed by using the plasma generated by the supplied microwave.

A silicon wafer having a diameter of 300 mm is used as the processing target substrate 0113. An RF bias power supply (not shown) is connected to the processing target substrate 0113 via the automatic matching device, and can apply an RF bias voltage. Due to a direct current bias voltage generated accordingly, ions in the plasma are drawn to a surface of the processing target substrate, and high speed and high quality of the plasma etching process can be achieved.

The static magnetic field generator 0109 can be provided around the plasma processing chamber 0114 and the like so as to apply a static magnetic field to the plasma processing chamber 0114. The static magnetic field generator 0109 includes an electromagnet formed by a plurality of solenoid coils, and a yoke for reducing a leakage flux and efficiently applying a static magnetic field to the plasma processing chamber 0114. The yoke is a steel yoke. A magnitude and a distribution of the static magnetic field applied to the plasma processing chamber 0114 can be adjusted by adjusting a value of a current flowing in the plurality of solenoid coils. The static magnetic field is substantially parallel to the central axis of the circular waveguide 0107, and is parallel to a supply direction of the microwave. A static magnetic field of 0.0875 tesla that causes electron cyclotron resonance can be generated in the plasma processing chamber 0114, and a position thereof can be adjusted.

The circle-rectangle converter 0106 is provided with a measuring instrument 0105 for optically observing the processing target substrate 0113. The measuring instrument 0105 optically observes the processing target substrate 0113 placed on the placing table 0115 via the circularly polarized wave generator 0108, the circular waveguide 0107, the cavity portion 0110, the dielectric window 0111, and the shower plate 0112.

An optical axis of the measuring instrument 0105 is set at a position slightly shifted from a center of the processing target substrate 0113. Therefore, the optical axis of the measuring instrument 0105 is at a position away from the central axis of the circular waveguide 0107.

A progress status of the plasma etching process on the processing target substrate can be observed in situ, and the high speed and the high quality of the plasma process can be achieved. For example, by stopping the process at a time when a film thickness reaches a desired film thickness, it is possible to reduce an unnecessary processing time and improve the processing accuracy. For example, in the measurement of the film thickness, optical interferences caused by a surface of a processing target film and a base layer can be used. Interference light may be incident on the processing target substrate from the outside, or light emitted from the plasma in the processing chamber may be used.

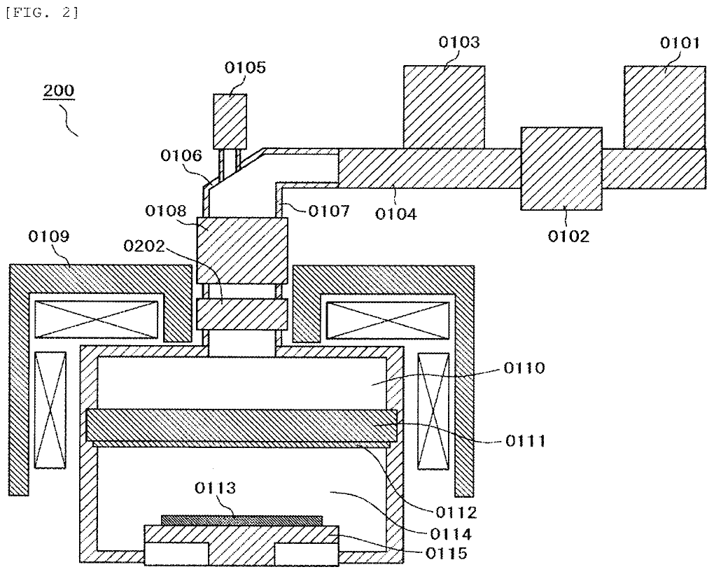

FIG. 2 illustrates a plasma processing apparatus 200 that performs the plasma etching process according to the first embodiment. The invention is applied to the example in the related art illustrated in FIG. 1, common parts are denoted by the same reference numerals, and the description thereof will be omitted. In the plasma processing apparatus 200 according to the present embodiment, with respect to the plasma processing apparatus 100 in the related art described with reference to FIG. 1, reflected wave generators 0202(a) to (c) are formed inside a waveguide 0201 that is connected to the circular waveguide 0107 and provided on a load side of the circularly polarized wave generator 0108.

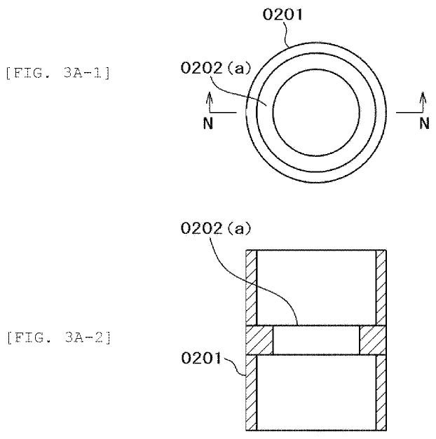

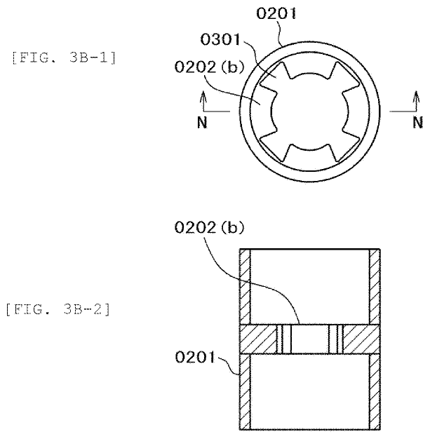

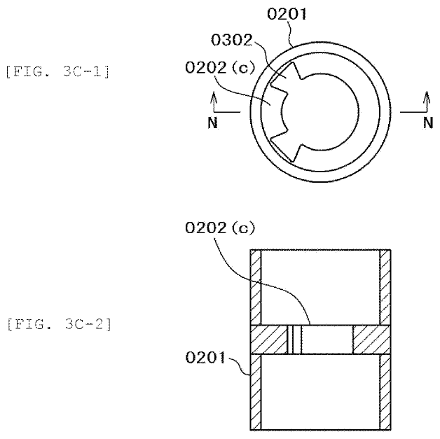

FIGS. 3A-1 to 3C-2 illustrate structures of the reflected wave generators 0202(a) to (c) formed inside the waveguide 0201. Each of FIGS. 3A-1 to 3C-2, FIGS. 3A-1, 3B-1, and 3C-1 illustrates a plan view, and each of FIGS. 3A-2, 3B-2, and 3C-2 illustrates a cross-sectional view taken along N-N in FIGS. 3A-1, 3B-1, and 3C-1, respectively.

The reflected wave generator 0202(a) in FIGS. 3A-1 and 3A-2 has a structure implemented by a short circular waveguide whose inner diameter is reduced similarly to that of the circular waveguide 0502 serving as the discontinuous portion described with reference to FIG. 5, and an axial length of a portion having the reduced diameter is 25 mm. The circular waveguide having the reduced diameter and constituting the reflected wave generator 0202(a) shares a central axis with the circular waveguides 0201 connected to upper and lower portions thereof, and is not eccentric.

As described with reference to FIG. 1, the optical axis of the measuring instrument 0105 is set at a position slightly shifted from the center of the processing target substrate 0113 placed on the placing table 0115, so that the optical axis of the measuring instrument 0105 is at a position away from the central axis of the circular waveguide 0107. Therefore, the reflected wave generator 0202(a) interferes with a visual field of the measuring instrument 0105. In order to avoid the interference, it is necessary to provide a notch, on a reflected wave generator 0202(a) side, in a portion where the reflected wave generator 0202(a) overlaps the visual field of the measuring instrument 0105.

The reflected wave generator 0202(b) in FIGS. 3B-1 and 3B-2 has a structure in which four notches 0301 having the same shape are provided in the reflected wave generator 0202(a) illustrated in FIGS. 3A-1 and 3A-2 every 90 degrees in an azimuth angle direction. Similarly, the reflected wave generator 0202(c) illustrated in FIGS. 3C-1 and 3C-2 has a structure in which two notches 0302 having the same shape are provided in the reflected wave generator 0202(a) illustrated in FIGS. 3A-1 and 3A-2 at an interval of 90 degrees in the azimuth angle direction.

As described above, it is necessary that the reflected wave generators 0202(a) to 0202(c) do not inhibit the circularly polarized wave. In the reflected wave generator 0202(a), the scattering matrix is the same regardless of a position of the polarization plane, and the circularly polarized wave is clearly not inhibited.

In the TE₁₁ mode in which the polarization planes are different from each other by 90 degrees in the azimuth angle direction in each of the reflected wave generators 0202(b) and 0202(c), the notches 0301 and 0302 are located at the same position with respect to the corresponding polarization planes, so that the scattering matrix is also the same in the TE₁₁ mode. Therefore, the circularly polarized wave is not inhibited as in the reflected wave generator 0202(a).

Although an example in which the notches having the same shape are provided at four positions at equal intervals in the azimuth angle direction in the reflected wave generator 0202(b) in FIGS. 3B-1 and 3B-2 is shown, the notches having the same shape may be provided at three positions at equal intervals, at five positions at equal intervals, or at six positions at equal intervals in the same manner.

By providing the notches 0301 and 0302, there is an effect of increasing a degree of freedom in setting the optical path of the measuring instrument 0105 for optically observing the processing target substrate 0113 placed on the placing table 0115.

By adjusting, according to the reflection coefficient of the load, the magnitude and the phase of the reflected waves generated by each of the reflected wave generators 0202(a) to (c) illustrated in FIGS. 3A-1 to 3C-2, the reflection coefficient on the load side obtained via the reflected wave generators 0202(a) to (c) can be ideally set to zero. A procedure of the adjustment will be described below. First, the scattering matrix of any one of the reflected wave generators 0202(a) to (c) is prepared in advance by calculation or measurement as shown in Table 1. Further, the reflection coefficient of the load is obtained by measurement or calculation.

For example, when an in-waveguide wavelength λ_{g} (m) in the TE₁₁ mode which is the lowest-order mode of the circular waveguide having a radius a (m), is a frequency f (Hz), the in-waveguide wavelength λ_{g} (m) can be calculated using Formula 8.

$$\begin{matrix}[ MATH . 8 ] & \\ {λ}_{g} = \frac{C}{f \sqrt{1 - {( \frac{1.841 c}{2 π fa} )}^{2}}} & ( Formula 8 )\end{matrix}$$

Here, c is a speed of light (m/s). Regarding the circular waveguide having the inner diameter of 90 mm, when the frequency is 2.45 GHz, it follows from (Formula 8) that the wavelength in the TE₁₁ mode is 202.5 mm.

Further, the scattering matrix of the circular waveguide having the length L in the TE₁₁ mode is obtained by using (Formula 2). By using the reflection coefficient of the load, (Formula 2) and (Formula 8), the reflection coefficient when the circular waveguide having the length L is connected to the load can be obtained. When the loss of the circular waveguide can be ignored, the reflection coefficient after the circular waveguide is connected is the same in the magnitude, and only changes in the phase as compared with that before the connection.

The phase of the reflection coefficient of the load can be adjusted by changing the length L of the circular waveguide. Further, an overall scattering matrix can be obtained after a reflected wave generator (corresponding to the reflected wave generators 0202(a) to (c)) is connected. That is, when the circular waveguide having the length L (corresponding to the circular waveguides 0107 and 0201) and the reflected wave generator (corresponding to the reflected wave generators 0202(a) to (c)) are connected to the load, a microwave circuit having one port is obtained, and the overall reflection coefficient can be obtained based on the scattering matrix and the like. Optimum values of the length L of the waveguide and an inner diameter of the reflected wave generator (corresponding to the reflected wave generators 0202(a) to (c)) can be obtained with a fact that the reflected wave is minimized as a reference. By applying the obtained optimal values, the reflection coefficient on the load side can decrease.

By preparing a large number of pieces of data corresponding to Table 1, it is possible to further reduce the magnitude of the reflection coefficient on the load side.

As described above, according to the present embodiment, in the plasma processing apparatus that uses the plasma generated by the radio frequency power of the microwave, the discontinuous portion (the reflected wave generator) is loaded on the load side of the circularly polarized wave generator and inside the circular waveguide, and the wave for canceling the reflected wave generated by the load is generated by the discontinuous portion according to the reflection coefficient of the load, the amplitude and the phase of the wave generated by the discontinuous portion are adjusted according to the reflection coefficient of the load, the discontinuous portion is implemented by the short circular waveguide whose inner diameter is reduced, the amplitude of the wave is adjusted by the shape (an inner diameter of an aperture), and the phase is adjusted by an axial position of the aperture.

Accordingly, according to the present embodiment, it is possible to implement the structure that does not inhibit the circularly polarized wave propagating in the circular waveguide, and has substantially any reflection coefficient. Then, by adjusting the magnitude of the reflection coefficient and the phase of the circularly polarized wave to cancel the reflected wave from the plasma processing chamber side to the waveguide side, the loss of the microwave power can be suppressed, and the occurrence of the abnormal discharge can be suppressed.

The plurality of notches 0301 or 0302 are formed at symmetrical positions in the azimuth angle direction with respect to a center in the reflected wave generator 0202(b) or 0202(c) constituting the discontinuous portion, and the positions of the notches 0301 or 0302 are set to be symmetrical to thereby not inhibit the circularly polarized wave. In order to prevent the loss of the microwave, a material having a high conductivity is particularly used on the surface.

By providing the notches 0301 or the notches 0302 in the reflected wave generator 0202(b) or the reflected wave generator 0202(c) in this way, it is possible to secure the optical path for optically observing, by the measuring instrument 0105, the processing target substrate 0113 placed on the placing table 0115 in the plasma processing chamber 0114. Therefore, since the plasma process can be observed in situ, it is possible to achieve the high quality of the plasma process.

That is, according to the present embodiment, in the plasma processing apparatus that includes an in-situ observation unit, it is possible to implement the structure that does not inhibit the circularly polarized wave propagating in the circular waveguide and has substantially any reflection coefficient, and to adjust the magnitude and the phase of the reflection coefficient to cancel the reflected wave from the plasma processing chamber side. Therefore, it is possible to solve the problems, that is, the power loss and the abnormal discharge and efficiently and uniformly supply the microwave power to a member serving as a heating target, and it is possible to improve the quality of the plasma process and shorten the processing time while performing the in-situ observation in the plasma process.

### Embodiment 2

As a second embodiment, an example of a heating apparatus including a microwave source, a circular waveguide, a circularly polarized wave generator provided inside the circular waveguide, and a discontinuous portion provided on an output side of the circularly polarized wave generator is described in which the discontinuous portion has an axisymmetric structure that does not inhibit the circularly polarized wave, and can generate a wave for canceling a reflected wave without breaking an axial symmetry property of an electromagnetic field of a microwave, and the processing target can be heated with good uniformity.

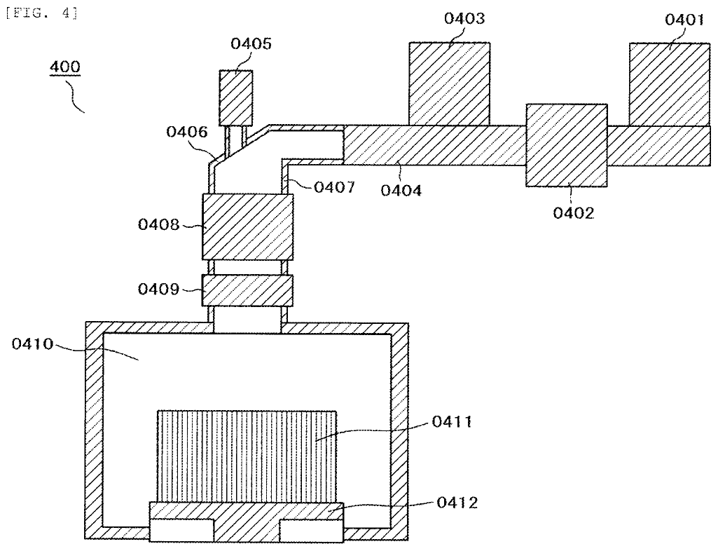

FIG. 4 illustrates a heating apparatus 400 according to the present embodiment. The heating apparatus 400 according to the present embodiment includes a microwave oscillator (a microwave generation source) 0401, an isolator 0402, a matching device 0403, a rectangular waveguide 0404, a measuring instrument 0405, a circle-rectangle converter 0406, a circular waveguide 0407, a circularly polarized wave generator 0408, a reflected wave generator 0409, a heating chamber 0410, and a placing table 0412 on which a sample 0411 is placed.

In such a configuration, the heating apparatus 400 generates a microwave having a frequency of 2.45 GHz by the microwave generation source 0401, and transmits the microwave by the rectangular waveguide 0404 via the isolator 0402 and the matching device 0403. As the rectangular waveguide 0404, a rectangular waveguide is used that operates in a TE₁₀ mode which is the lowest-order mode, and has an inner cross section of 109.2 mm×54.6 mm. A magnetron is used as the microwave generation source 0401. The isolator 0402 has a function of preventing the reflected wave from the load side from returning to and damaging the microwave generation source 0401. The matching device 0403 operates to eliminate the reflected wave generated by impedance mismatching of the load. A manual three-stub tuner is used as the matching device 0403, and an automatic matching device may be used.

Further, the microwave is introduced into the heating chamber 0410 by the circular waveguide 0407 via the circle-rectangle converter 0406. As the circular waveguide 0407, a circular waveguide that has an inner diameter of 90 mm and operates in the TE₁₁ mode which is the lowest-order mode is used. The circle-rectangle converter 0406 also has a function of bending a propagating direction of the microwave at a right angle.

The circularly polarized wave generator 0408 is provided inside the circular waveguide 0407, and converts the microwave incident as a linearly polarized wave into a circularly polarized wave. Further, the reflected wave generator 0409 is provided on a load side of the circularly polarized wave generator 0408, and has a function of generating a reflected wave. The reflected wave generator 0409 does not inhibit the circularly polarized wave. That is, when the circularly polarized wave is connected from an incident side, the reflected wave and the transmitted wave become the circularly polarized wave. The reflected wave generator 0409 has the same structure as those of the reflected wave generators 0202(a) to (c) each of which constitutes the discontinuous portion formed inside the waveguide 0201 described with reference to FIGS. 3A-1 to 3C-2 in Embodiment 1, and achieves the same operation and effect.

The placing table 0412 on which the sample 0411 is placed and the sample 0411 are provided in the heating chamber 0410. The heating chamber 0410 has a substantially cylindrical shape, and the placing table 0412 is disposed substantially coaxially with the heating chamber 0410 having the cylindrical shape. Further, the circular waveguide 0407 is coaxially connected to the heating chamber 0410. The circularly polarized wave generated by the circularly polarized wave generator 0408 is supplied to the heating chamber 0410 to heat the sample 0411.

In such a configuration, since a polarization plane of the circularly polarized wave generated by the circularly polarized wave generator 0408 rotates at a frequency of the microwave, absorption power thereof is smoothed in one cycle in the azimuth angle direction with respect to a central axis of the circular waveguide 0407. That is, it is possible to achieve, by the circularly polarized wave, an absorption power distribution that is uniform in the azimuth angle direction. Therefore, heating unevenness of the sample 0411 in the azimuth angle direction can be reduced.

Further, as described in Embodiment 1, by adjusting a magnitude and a phase of the reflected wave generated by the reflected wave generator 0409 to optimal values corresponding to the reflection coefficient of the load, the reflected wave can be reduced and supplied power can be effectively used for heating the sample 0411. In addition, a burden on the matching device 0403 can be reduced.

Further, as described above, the circularly polarized wave generator 0408 is often optimized for a matching load, and an axial ratio may be deteriorated in a case of a mismatching load, but an operation failure of the circularly polarized wave generator 0408 can be prevented by using the reflected wave generator 0409.

According to the present embodiment, the discontinuous portion for generating a desired reflected wave is provided at a predetermined position in the waveguide, and the reflected wave generated by the discontinuous portion cancels the reflected wave generated on the load side of the waveguide, so that the microwave power can be efficiently and uniformly supplied to a member serving as a heating target.

While the invention made by the inventor has been described in detail based on the embodiments, the invention is not limited to the embodiments described above, and various modifications can be made without departing from the scope of the invention. For example, the embodiments described above have been described in detail for easy understanding of the invention, and the invention is not necessarily limited to those including all of the configurations described above. Further, a part of the configuration of each embodiment can be added to, deleted from, or replaced with another configuration.

### REFERENCE SIGNS LIST

100, 200 plasma processing apparatus
0101, 0401 microwave oscillator
0102, 0402 isolator
0103 automatic matching device
0104, 0404 rectangular waveguide
0105, 0405 measuring instrument for optical observation
0106, 0406 circle-rectangle converter
0107, 0201, 0407 circular waveguide
0108, 0408 circularly polarized wave generator
0109 static magnetic field generator
0110 cavity portion
0111 dielectric window
0112 shower plate
0113 processing target substrate
0114 plasma processing chamber
0115, 0412 placing table
0202, 0202(a), 0202(b), 0202(c), 0409 reflected wave generator
0301, 0302 notch
0403 matching device
0410 heating chamber
0411 sample
0501 circular waveguide
0502 circular waveguide constituting discontinuous portion
0503 circular waveguide
0504 port 1
0505 port 2

1. A plasma processing apparatus, comprising:
a processing chamber configured to plasma-process a sample;
a radio frequency power supply configured to supply, via a circular waveguide, radio frequency power of a microwave;
a monitor device configured to optically monitor a plasma state via the circular waveguide;
a circularly polarized wave generator disposed inside the circular waveguide and configured to generate a circularly polarized wave; and
a sample stage allowing the sample to be placed thereon, wherein
the plasma processing apparatus further comprises a reflected wave generator disposed between the circularly polarized wave generator and the processing chamber and inside the circular waveguide,
the reflected wave generator generates a reflected wave that cancels, without inhibiting the circularly polarized wave, a reflected wave propagating from the processing chamber, and
an optical path for optically monitoring the plasma state is formed in the reflected wave generator.

2. The plasma processing apparatus according to claim 1, wherein
a central axis of the reflected wave generator is the same as a central axis of the circular waveguide.

3. The plasma processing apparatus according to claim 1, wherein
an inner diameter of the reflected wave generator is defined based on a reflection coefficient of a load.

4. The plasma processing apparatus according to claim 1, wherein
a position of the reflected wave generator in a direction of a central axis of the reflected wave generator is defined based on a reflection coefficient of a load.

5. The plasma processing apparatus according to claim 3, wherein
a position of the reflected wave generator in a direction of a central axis of the reflected wave generator is defined based on the reflection coefficient of the load.

6. The plasma processing apparatus according to claim 1, wherein
the reflected wave generator includes a plurality of notched portions.

7. The plasma processing apparatus according to claim 6, wherein
each of the notched portions is formed at a position the same with a polarization plane of the circularly polarized wave.

8. A heating apparatus, comprising:
a heating chamber configured to heat a sample;
a radio frequency power supply configured to supply, via a circular waveguide, radio frequency power of a microwave; and
a circularly polarized wave generator disposed inside the circular waveguide and configured to generate a circularly polarized wave, wherein
the heating apparatus further comprises a reflected wave generator disposed between the circularly polarized wave generator and the heating chamber and inside the circular waveguide, and
the reflected wave generator generates a reflected wave that cancels, without inhibiting the circularly polarized wave, a reflected wave propagating from the heating chamber.
